(19) United States
(12) Patent Application Publication
(10) Pub. No.: US 2021/0408489 A1
(43) Pub. Date: Dec. 30, 2021

(54) DISPLAY PANEL AND MIRROR DISPLAY APPARATUS

(71) Applicant: BOE TECHNOLOGY GROUP CO., LTD., Beijing (CN)

(72) Inventors: Xueyan Tian, Beijing (CN); Xinshe Yin, Beijing (CN); Wenxiu Zhu, Beijing (CN); Guoyi Cui, Beijing (CN)

(73) Assignee: BOE TECHNOLOGY GROUP CO., LTD.

(21) Appl. No.: 17/352,491

(22) Filed: Jun. 21, 2021

(30) Foreign Application Priority Data
Jun. 30, 2020 (CN) 202010617130.5

(51) Int. Cl. H01L 51/52; H01L 27/32

(52) U.S. Cl. CPC H01L 51/5271; H01L 51/5237; H01L 51/5284; H01L 27/3246

(57) ABSTRACT

The present disclosure provides a display panel and a mirror display apparatus. The display panel includes a base substrate, a pixel defining layer and a light adjusting layer. The pixel defining layer is disposed on the base substrate and defines a plurality of light-emitting areas. The light adjusting layer includes a first reflecting layer, which is disposed at a side of the pixel defining layer away from the base substrate and has first openings in areas corresponding to the light-emitting areas. The light adjusting layer is configured to block at least a part of light directed at adjacent light-emitting areas for each of the light-emitting areas.

This application claims priority to the Chinese Patent Application No. 202010617130.5, filed on Jun. 30, 2020, and entitled “ORGANIC LIGHT-EMITTING DISPLAY PANEL AND MIRROR DISPLAY APPARATUS”, the content of which is incorporated herein by reference in its entirety.

### TECHNICAL FIELD

The present disclosure relates to a display panel and a mirror display apparatus.

### BACKGROUND

A mirror display apparatus has both a display function and a mirror reflection function, and can be applicable to rear view mirrors of vehicles and cosmetic mirrors etc. Generally, a mirror display apparatus includes a display panel and a reflecting layer disposed on a light-exit surface of the display panel. The reflecting layer covers a part of the light-exit surface of the display panel. An area of the display panel disposed with the reflecting layer realizes the mirror reflection function, and an area of the display panel not disposed with the reflecting layer is configured to display images.

### SUMMARY

The present disclosure provides a display panel and a mirror display apparatus. The technical solutions are as below.

According to a first aspect, there is provided a display panel. The display panel includes:

a base substrate;

a pixel defining layer disposed on the base substrate and defining a plurality of light-emitting areas; and

a light adjusting layer including a first reflecting layer, wherein the first reflecting layer is disposed at a side of the pixel defining layer away from the base substrate, and has first openings in areas corresponding to the light-emitting areas,

wherein the light adjusting layer is configured to block at least a part of light directed at adjacent light-emitting areas for each of the light-emitting areas.

Optionally, for each of the first openings, a size of the first opening is larger than that of a corresponding light-emitting area; and on the base substrate, an orthogonal projection of the first opening covers an orthogonal projection of the corresponding light-emitting area.

Optionally, the light adjusting layer further includes a second reflecting layer disposed at the side of the pixel defining layer away from the base substrate; and on the base substrate, an orthogonal projection of the second reflecting layer is within an orthogonal projection of the light-emitting areas, and an area of the orthogonal projection of the second reflecting layer is smaller than that of the orthogonal projection of the light-emitting areas.

Optionally, for each of the first openings, an orthogonal projection of the first opening on the base substrate covers an orthogonal projection of a corresponding light-emitting area on the base substrate.

Optionally, the second reflecting layer and the first reflecting layer are disposed in the same layer.

Optionally, the first reflecting layer further includes light-leaking gaps; and on the base substrate, an orthogonal projection of the light-leaking gaps is staggered from an orthogonal projection of the light-emitting areas.

Optionally, the light-leaking gaps are disposed to surround the light-emitting area.

Optionally, for each of the first openings, an orthogonal projection of the first opening on the base substrate covers an orthogonal projection of a corresponding light-emitting area on the base substrate.

Optionally, the light adjusting layer further includes a light absorbing layer disposed between the pixel defining layer and the first reflecting layer and including second openings; and on the base substrate, an orthogonal projection of the second openings overlaps with an orthogonal projection of the first openings.

Optionally, for each of the first openings, an orthogonal projection of the first opening on the base substrate covers an orthogonal projection of a corresponding light-emitting area on the base substrate.

Optionally, a material of the light absorbing layer includes at least one of black MoO₃ and a black resin.

Optionally, the first reflecting layer is a one-layer film, and a material of the first reflecting layer includes at least one of Mo, Al, Ti and Ag.

Optionally, the first reflecting layer includes a first film layer, a second film layer and a third film layer which are laminated, and the first film layer, the second film layer and the third film layer satisfy one of the followings:

materials of the first film layer and the third film layer are both Ti, and a material of the second film layer is Al;

materials of the first film layer and the third film layer are both ITO, and a material of the second film layer is Ag.

Optionally, the second reflecting layer is a one-layer film, and a material of the second reflecting layer includes at least one of Mo, Al, Ti and Ag.

Optionally, the second reflecting layer includes a first film layer, a second film layer and a third film layer which are laminated, and the first film layer, the second film layer and the third film layer satisfy one of the followings:

materials of the first film layer and the third film layer are both Ti, and a material of the second film layer is Al;

materials of the first film layer and the third film layer are both ITO, and a material of the second film layer is Ag.

Optionally, the display panel further includes:

a switch unit disposed between the base substrate and the pixel defining layer;

a light-emitting unit disposed in the light-emitting area and connected to the switch unit; and

an encapsulating structure disposed between the light-emitting unit and the first reflecting layer.

Optionally, the switch unit of the display panel includes at least one of a low-temperature polycrystalline silicon thin film transistor and a metal oxide thin film transistor.

Optionally, the encapsulating structure is a thin film encapsulation structure.

Optionally, for each of the first openings, a size of the first opening is larger than that of a corresponding light-emitting area; and on the base substrate, an orthogonal projection of the first opening covers an orthogonal projection of the corresponding light-emitting area; the first reflecting layer further includes light-leaking gaps disposed to surround the light-emitting area;

the light adjusting layer further includes a second reflecting layer and a light-absorbing layer; the second reflecting layer is disposed at the side of the pixel defining layer away from the base substrate; on the base substrate, an orthogonal projection of the second reflecting layer is within an orthogonal projection of the light-emitting areas, and an area of the orthogonal projection of the second reflecting layer is smaller than that of the orthogonal projection of the light-emitting areas; the light absorbing layer is disposed between the pixel defining layer and the first reflecting layer and includes second openings; and on the base substrate, an orthogonal projection of the second openings overlaps with an orthogonal projection of the first openings; and

the display panel further includes: a switch unit disposed between the base substrate and the pixel defining layer; a light-emitting unit disposed in the light-emitting area and connected to the switch unit; and an encapsulating structure disposed between the light-emitting unit and the first reflecting layer.

According to a second aspect, a mirror display apparatus is provided. The mirror display apparatus includes the display panel according to the first aspect or the display panel according to any optional implementation of the first aspect.

### BRIEF DESCRIPTION OF THE DRAWINGS

FIG. 1 is a front view of a display panel according to an embodiment of the present disclosure;

FIG. 2 is a schematic diagram of a part of a display panel according to an embodiment of the present disclosure;

FIG. 3 is a sectional view of position A-A′ of the display panel shown in FIG. 2;

FIG. 4 is a schematic diagram of a part of another display panel according to an embodiment of the present disclosure;

FIG. 5 is a sectional view of position B-B′ of the display panel shown in FIG. 4;

FIG. 6 is a schematic diagram of a part of still another display panel according to an embodiment of the present disclosure;

FIG. 7 is a sectional view of position C-C′ of the display panel shown in FIG. 6;

FIG. 8 is a sectional view of still another display panel according to an embodiment of the present disclosure; and

FIG. 9 is a sectional view of still another display panel according to an embodiment of the present disclosure.

### DETAILED DESCRIPTION

Embodiments of the present disclosure are described below in conjunction with accompanying drawings. The same or similar reference numerals shown in the accompanying drawings represent the same or similar elements, or represent elements with the same or similar functions. The embodiments described below with reference to the accompanying drawings are exemplary, are only used to explain the present disclosure, and are not understood as a limitation to the present disclosure.

A mirror display apparatus has both a display function and a mirror reflection function. A general mirror display apparatus includes a display panel and a transflective film disposed on a light-exit surface of the display panel. Light emitted by the display panel is partially transmitted by the transflective film, so that the display panel may realize the display function. The transflective film may reflect external light, so that the display panel may realize the mirror reflection function. However, the transflective film may easily affect light transmittance of the display panel, resulting in low light transmittance of the display panel. Moreover, affected by reflected light from the outside, contrast of a picture displayed by the mirror display apparatus is low, and a display effect is poor.

Currently, there is another mirror display apparatus. The mirror display apparatus includes a display panel and a reflecting layer disposed on a light-exit surface of the display panel. The reflecting layer covers a part of the light-exit surface of the display panel. An area of the display panel disposed with the reflecting layer realizes the mirror reflection function, and an area of the display panel not disposed with the reflecting layer is configured to display images. However, light emitted by sub-pixels of the display panel is not completely perpendicular to the light-exit surface of the display panel, and a part of the light emitted by the sub-pixels is scattered. When hitting the reflecting layer, the scattered light may be reflected by the reflecting layer to an area where another sub-pixel is disposed, and finally be emitted from the light-exit surface of the display panel through the area where the another sub-pixel is disposed. As a result, the display panel suffers from cross-color and color-mixing defects.

In view of the problems of an existing mirror display apparatus, embodiments of the present disclosure provide a display panel and a mirror display apparatus. In the embodiments of the present disclosure, the display panel includes a light adjusting layer. The light adjusting layer includes a first reflecting layer, and is configured to block at least a part of light directed at adjacent light-emitting areas for each of the light-emitting areas. The first reflecting layer can realize a mirror reflection function of a display panel, and the display panel also has a display function. Since the first reflecting layer realizes the mirror reflection function of the display panel (i.e., the mirror reflection function of the display panel is realized by reflection), a light transmission rate of the display panel is high and good display effect is produced. Since the light adjusting layer can block at least a part of light directed at adjacent light-emitting areas for each of the light-emitting areas, cross-color and poor color-mixing of the display panel can be alleviated.

The followings will introduce the technical solutions of the present disclosure with reference to the drawings.

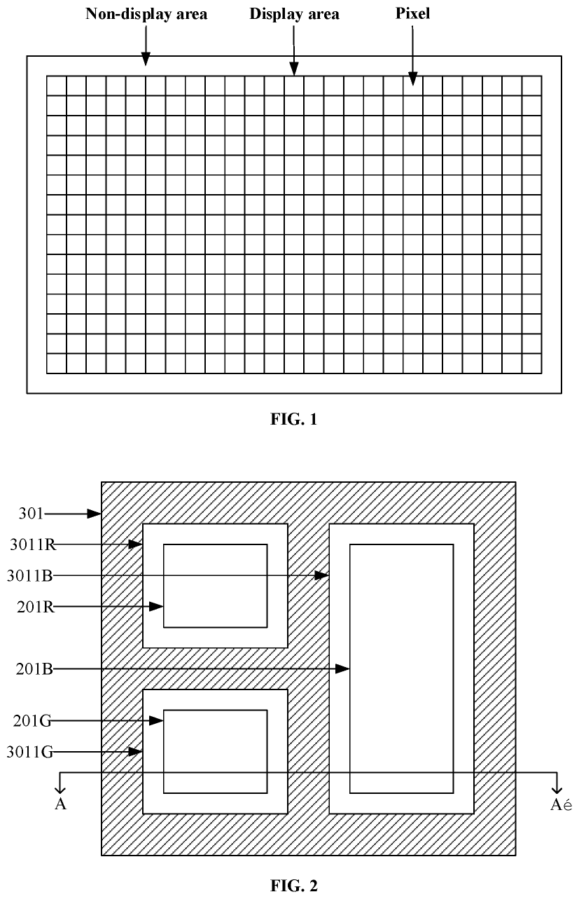

FIG. 1 is a front view of a display panel according to an embodiment of the present disclosure. Referring to FIG. 1, the display panel includes a display area and a non-display area. The non-display area is disposed around the display area. There are multiple pixels in the display area, and there are wires (not shown in FIG. 1) in the non-display area for supplying power to the pixels. The pixels emit light according to electrical signals provided by the wires to realize the display function of the display panel. Each of the pixels may include sub-pixels of multiple colors. For example, each pixel in FIG. 1 includes a red (R) sub-pixel, a green (G) sub-pixel, and a blue (B) sub-pixel. In some embodiments, the display area is also referred to as an active area (AA) for displaying.

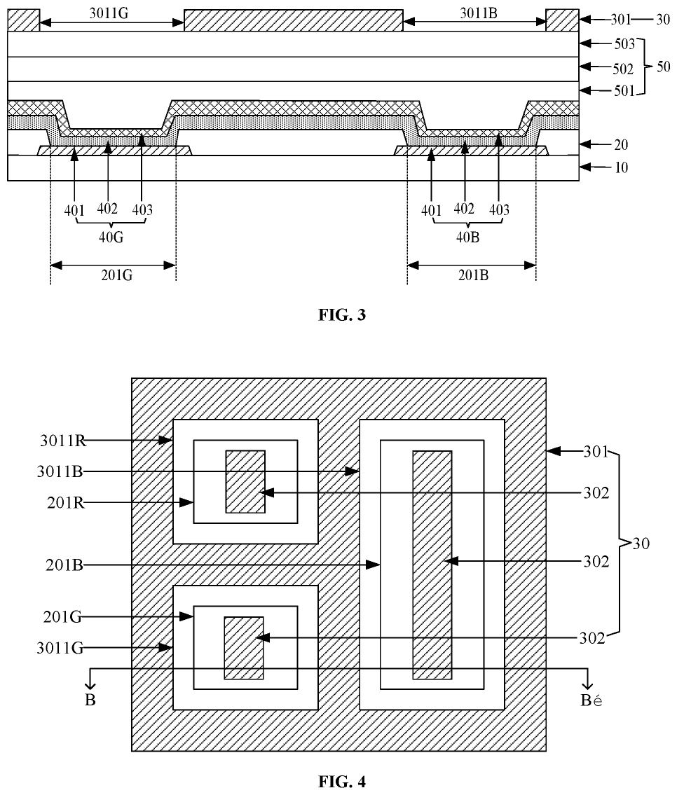

FIG. 2 is a schematic diagram of a part of a display panel according to an embodiment of the present disclosure, and FIG. 3 is a sectional view of position A-A′ of the display panel shown in FIG. 2. For example, FIG. 2 is a schematic diagram of one pixel of the display panel shown in FIG. 1. Referring to FIG. 2 and FIG. 3, the display panel includes a base substrate 10, a pixel defining layer 20 and a light adjusting layer 30. The pixel defining layer 20 is disposed in the base substrate 10 and defines a plurality of light-emitting areas 201 (a light-emitting area 201R, a light-emitting area 201G and a light-emitting area 201B in FIG. 2 and FIG. 3 are collectively referred to as the light-emitting areas 201). The light adjusting layer 30 includes a first reflecting layer 301. The first reflecting layer 301 is disposed at a side of the pixel defining layer 20 away from the base substrate 10, and includes first openings 3011 (a first opening 3011R, a first opening 3011G, and a first opening 3011B in FIG. 2 and FIG. 3 are collectively referred to as the first openings 3011) in its area corresponding to the light-emitting areas 201.

The light adjusting layer 30 is configured to block at least a part of light emitted from the light-emitting areas 201 from emitting from adjacent light-emitting areas of the light-emitting areas 201. For example, the light-emitting area 201R is configured to emit red light, the light-emitting area 201G is configured to emit green light, and the light-emitting area 201B is configured to emit blue light. The light adjusting layer 30 is configured to block at least a part of red light emitted from the light-emitting area 201R from emitting from the light-emitting area 201G and the light-emitting area 201B, block at least a part of green light emitted from the light-emitting area 201G from emitting from the light-emitting area 201R and the light-emitting area 201B, and block at least a part of blue light emitted from the light-emitting area 201B from emitting from the light-emitting area 201R and the light-emitting area 201G.

In summary, the display panel provided by the embodiment of the present disclosure includes the light adjusting layer, the light adjusting layer includes a first reflecting layer, and the light adjusting layer is configured to block at least a part of light emitted from the light-emitting areas from emitting from adjacent light-emitting areas. The first reflecting layer may realize the mirror reflection function of the display panel, and the display panel also has the display function. Since the mirror reflection function of the display panel is realized by the first reflecting layer (that is, the mirror reflection function of the display panel is realized by reflection), light transmittance of the display panel is higher and a display effect thereof is better. Since the light adjusting layer can block at least a part of light directed at adjacent light-emitting areas for each of the light-emitting areas, cross-color and poor color-mixing of the display panel can be alleviated.

In the embodiment of the present disclosure, the light adjusting layer 30 may block at least a part of light emitted from the light-emitting areas 201 from emitting from adjacent light-emitting areas of the light-emitting areas 201 by at least one of the following four implementing modes.

For a first implementing mode, as shown in FIG. 2 and FIG. 3, the light adjusting layer 30 includes a first reflecting layer 301, and the first reflecting layer 301 is disposed at a side of the pixel defining layer 20 away from the base substrate 10. The first reflecting layer 301 has first openings 3011 in its area corresponding to the light-emitting area 201. A size of the first opening 3011 is larger than that of the corresponding light-emitting area 201. On the base substrate 10, an orthogonal projection of the first opening 3011 covers an orthogonal projection of the corresponding light-emitting area 201.

The schematic diagram of FIG. 2 may show relation between projections of each of the light-emitting areas 201 and a corresponding first opening 3011. As shown in FIG. 2 and FIG. 3, the first opening 3011R corresponds to the light-emitting area 201R, a size of the first opening 3011R is larger than that of the light-emitting area 201R, and on the base substrate 10, an orthogonal projection of the first opening 3011R covers an orthogonal projection of the light-emitting area 201R; the first opening 3011G corresponds to the light-emitting area 201G, a size of the first opening 3011G is larger than that of the light-emitting area 201G, and on the base substrate 10, an orthogonal projection of the first opening 3011G covers an orthogonal projection of the light-emitting area 201G; and the first opening 3011B corresponds to the light-emitting area 201B, a size of the first opening 3011B is larger than that of the light-emitting area 201B, and on the base substrate 10, an orthogonal projection of the first opening 3011B covers an orthogonal projection of the light-emitting area 201B.

In the first implementing mode, a size of each of the first openings 3011 is greater than that of a corresponding light-emitting area 201, and on the base substrate 10, an orthogonal projection of the first opening 3011 covers an orthogonal projection of the corresponding light-emitting area 201. Therefore, among light emitted by each of the light-emitting areas 201 (for example, the light-emitting area 201R), at least a part of light (i.e., scattered light) directed to an interval area may be emitted from a first opening 3011 (for example, the first opening 3011R) corresponding to the light-emitting area 201, so that the at least a part of light may not be emitted from adjacent light-emitting areas (for example, the light-emitting area 201G and/or the light-emitting area 201B) of the light-emitting area 201. In this way, the first reflecting layer 301 blocks the at least a part of light from emitting from the adjacent light-emitting areas of the light-emitting area 201 through the first opening 3011, so that the light adjusting layer 30 may block the at least a part of light from emitting from the adjacent light-emitting areas of the light-emitting area 201. The interval area refers to an area between the light-emitting areas 201 and adjacent light-emitting areas of the light-emitting areas 201.

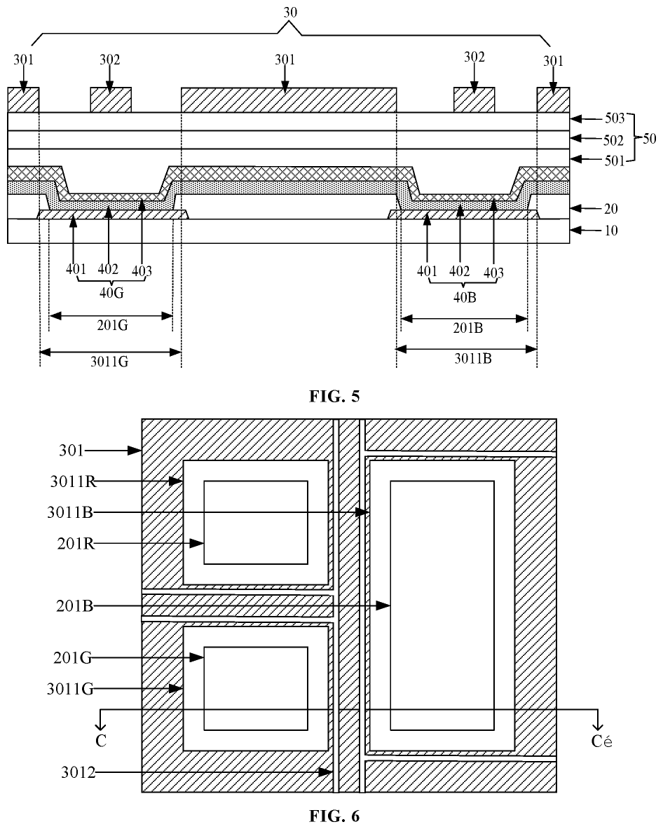

For a second implementing mode, FIG. 4 and FIG. 5 are referred to, wherein FIG. 4 is a schematic diagram of a part of another display panel according to an embodiment of the present disclosure, and FIG. 5 is a sectional view of position B-B′ of the display panel shown in FIG. 4. For example, FIG. 4 is a schematic diagram of one pixel of the display panel shown in FIG. 1. Referring to FIG. 4 and FIG. 5, the light adjusting layer 30 includes the first reflecting layer 301 and a second reflecting layer 302. The first reflecting layer 301 is disposed at a side of the pixel defining layer 20 away from the base substrate 10, and includes first openings 3011 (the first opening 3011R, the first opening 3011G, and the first opening 3011B in FIG. 4 and FIG. 5 are collectively referred to as the first openings 3011) in its area corresponding to the light-emitting areas 201. The second reflecting layer 302 is disposed at the side of the pixel defining layer 20 away from the base substrate 10; and on the base substrate 10, an orthogonal projection of the second reflecting layer 302 is within an orthogonal projection of the light-emitting area 201, and an area of the orthogonal projection of the second reflecting layer 302 is smaller than that of the orthogonal projection of the light-emitting area 201.

As shown in FIG. 5, the first reflecting layer 301 and the second reflecting layer 302 are disposed in the same layer. In this way, the first reflecting layer 301 and the second reflecting layer 302 may be prepared at the same time, thereby simplifying a manufacturing process of the display panel.

Optionally, on the base substrate 10, the orthogonal projection of the second reflecting layer 302 is disposed at a center of the orthogonal projection of the corresponding light-emitting area 201.

In the second implementing mode, the light adjusting layer 30 includes the second reflecting layer 302, and on the base substrate 10, the orthogonal projection of the second reflecting layer 302 is within the orthogonal projection of the corresponding light-emitting area 201. Therefore, among light emitted by each of the light-emitting areas 201 (for example, the light-emitting area 201R), at least a part of light (i.e., scattered light) directed to adjacent light-emitting areas (for example, the light-emitting area 201G and/or the light-emitting area 201B) of the light-emitting area 201 may be reflected by the second reflecting layer 302 corresponding to the adjacent light-emitting areas 201, so that the at least a part of light may not be emitted from the adjacent light-emitting areas. In this way, the second reflecting layer 302 blocks the at least a part of light from emitting from the adjacent light-emitting areas of the light-emitting area 201, so that the light adjusting layer 30 may block the at least a part of light from emitting from the adjacent light-emitting areas of the light-emitting area 201. Further, on the base substrate 10, the area of the orthogonal projection of the second reflecting layer 302 is smaller than that of the orthogonal projection of the corresponding light-emitting area 201. Therefore, light emitted from each light-emitting area 201 may be emitted through a corresponding first opening 3011, so as to ensure normal displaying of the display panel. Compared with an implementing mode (for example, the first implementing mode) in which only the first reflecting layer 301 is provided, further providing the second reflecting layer 302 can increase mirror surface reflectance of the display panel, thereby better realizing the mirror reflection function of the display panel.

Optionally, in the second implementing mode, on the base substrate 10, the orthogonal projection of the first opening 3011 covers the orthogonal projection of the corresponding light-emitting area 201. The size of the first opening 3011 may be greater than that of the corresponding light-emitting area 201, then on the base substrate 10, the area of the orthogonal projection of the first opening 3011 is greater than that of the orthogonal projection of the corresponding light-emitting area 201; alternatively, the size of the first opening 3011 may be equal to that of the corresponding light-emitting area 201, then on the base substrate 10, the area of the orthogonal projection of the first opening 3011 is equal to that of the orthogonal projection of the corresponding light-emitting area 201. Though in FIG. 4 and FIG. 5, the size of the first opening 3011 is greater than that of the corresponding light-emitting area 201 as an example, this is not a limitation on embodiments of the present disclosure, and in other embodiments, a size of the first opening may be equal to that of the corresponding light-emitting area.

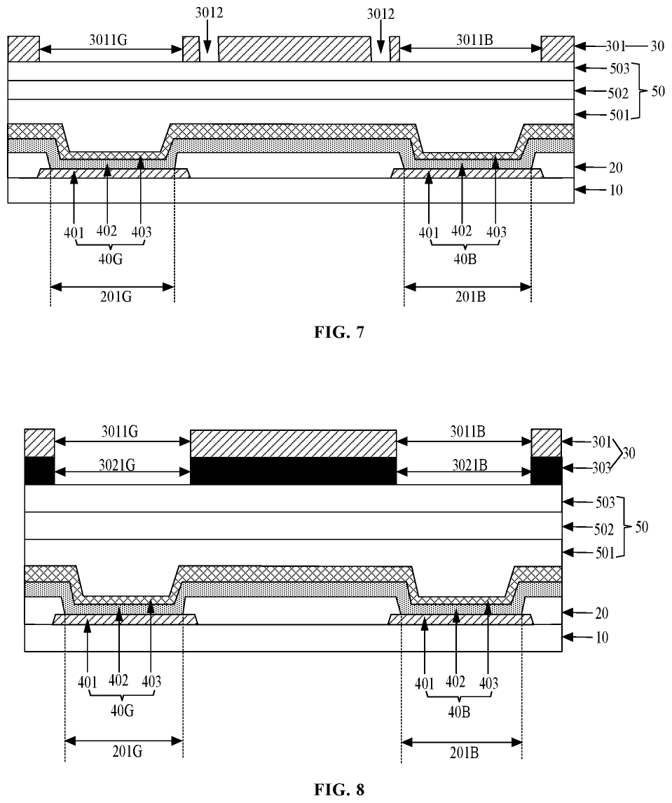

For a third implementing mode, FIG. 6 and FIG. 7 are referred to, wherein FIG. 6 is a schematic diagram of a part of still another display panel according to an embodiment of the present disclosure, and FIG. 7 is a sectional view of position C-C′ of the display panel shown in FIG. 6. For example, FIG. 6 is a schematic diagram of one pixel of the display panel shown in FIG. 1. Referring to FIG. 6 and FIG. 7, the light adjusting layer 30 includes a first reflecting layer 301. The first reflecting layer 301 is disposed at a side of the pixel defining layer 20 away from the base substrate 10, and includes first openings 3011 (the first opening 3011R, the first opening 3011G, and the first opening 3011B in FIG. 6 and FIG. 7 are collectively referred to as the first openings 3011) in its area corresponding to the light-emitting areas 201. The first reflecting layer 301 also has light-leaking gaps 3012, and on the base substrate 10, an orthogonal projection of the light-leaking gaps 3012 is staggered from an orthogonal projection of the light-emitting area 201. The light-leaking gap 3012 may be disposed to surround the light-emitting area 201.

In the third implementing mode, the first reflecting layer 301 has light-leaking gaps 3012, and on the base substrate 10, the orthogonal projection of the light-leaking gap 3012 is staggered form the orthogonal projection of the light-emitting area 201. Therefore, among light emitted by each of the light-emitting areas 201 (for example, the light-emitting area 201R), at least a part of light (i.e., scattered light) directed to the interval area may be emitted from the light-leaking gap 3012, so that the at least a part of light may not be emitted from adjacent light-emitting areas (for example, the light-emitting area 201G and/or the light-emitting area 201B) of the light-emitting area 201. In this way, the first reflecting layer 301 blocks the at least a part of light from emitting from the adjacent light-emitting areas of the light-emitting area 201 through the light-leaking gap 3012, so that the light adjusting layer 30 may block the at least a part of light from emitting from the adjacent light-emitting areas of the light-emitting area 201. The interval area refers to an area between the light-emitting areas 201 and adjacent light-emitting areas of the light-emitting areas 201.

Optionally, in the third implementing mode, on the base substrate 10, the orthogonal projection of the first opening 3011 covers the orthogonal projection of the corresponding light-emitting area 201. The size of the first opening 3011 may be greater than that of the corresponding light-emitting area 201, then on the base substrate 10, the area of the orthogonal projection of the first opening 3011 is greater than that of the orthogonal projection of the corresponding light-emitting area 201; alternatively, the size of the first opening 3011 may be equal to that of the corresponding light-emitting area 201, then on the base substrate 10, the area of the orthogonal projection of the first opening 3011 is equal to that of the orthogonal projection of the corresponding light-emitting area 201. Though in FIG. 6 and FIG. 7, the size of the first opening 3011 is greater than that of the corresponding light-emitting area 201 as an example, this is not a limitation on embodiments of the present disclosure, and in other embodiments, a size of the first opening may be equal to that of the corresponding light-emitting area.

For a fourth implementing mode, FIG. 8 is referred to, which is a sectional view of still another display panel according to an embodiment of the present disclosure. The light adjusting layer 30 includes a first reflecting layer 301 and a light absorbing layer 303. The first reflecting layer 301 is disposed at a side of the pixel defining layer 20 away from the base substrate 10, and includes first openings 3011 (the first opening 3011G and the first opening 3011B in FIG. 8 are collectively referred to as the first openings 3011) in its area corresponding to the light-emitting areas 201. The light absorbing layer 303 is disposed between the pixel defining layer 20 and the first reflecting layer 301, and includes second openings 3021 (the second opening 3021G and the second opening 3021B in FIG. 8 are collectively referred to as the second openings 3021). On the base substrate 10, an orthogonal projection of the second openings 3021 coincides with an orthogonal projection of a corresponding first opening 3011.

In the fourth implementing mode, the light adjusting layer 30 includes a light absorbing layer 303 disposed between the pixel defining layer 20 and the first reflecting layer 301. Therefore, among light emitted by each of the light-emitting areas 201 (for example, the light-emitting area 201R), at least a part of light (i.e., scattered light) directed to the interval area may be absorbed by the light absorbing layer 303, so that the at least a part of light may not be emitted from adjacent light-emitting areas (for example, the light-emitting area 201G and/or the light-emitting area 201B) of the light-emitting area 201. In this way, the light absorbing layer 303 blocks the at least a part of light from emitting from the adjacent light-emitting areas of the light-emitting area 201, so that the light adjusting layer 30 may block the at least a part of light from emitting from the adjacent light-emitting areas of the light-emitting area 201. The interval area refers to an area between the light-emitting areas 201 and adjacent light-emitting areas of the light-emitting areas 201.

On the base substrate 10, the orthogonal projection of the second openings 3021 coincides with the orthogonal projection of the corresponding first openings 3011. Therefore, the light absorbing layer 303 and the first reflecting layer 301 may be prepared by using the same mask, thereby simplifying a manufacturing process of the display panel.

Optionally, in the fourth implementing mode, on the base substrate 10, the orthogonal projection of the first opening 3011 covers the orthogonal projection of the corresponding light-emitting area 201. The size of the first opening 3011 may be greater than that of the corresponding light-emitting area 201, then on the base substrate 10, the area of the orthogonal projection of the first opening 3011 is greater than that of the orthogonal projection of the corresponding light-emitting area 201; alternatively, the size of the first opening 3011 may be equal to that of the corresponding light-emitting area 201, then on the base substrate 10, the area of the orthogonal projection of the first opening 3011 is equal to that of the orthogonal projection of the corresponding light-emitting area 201. Though in FIG. 8, the size of the first opening 3011 is greater than that of the corresponding light-emitting area 201 as an example, this is not a limitation on embodiments of the present disclosure, and in other embodiments, a size of the first opening may be equal to that of the corresponding light-emitting area.

Optionally, the light absorbing layer 303 may be a black matrix layer, or other film layer with a light absorbing function. A material of the light absorbing layer 303 may include at least one of black MoO₃ and a black resin. The black MoO₃ and the black resin are only examples of materials for the light absorbing layer 303 of the present disclosure, and do not limit the light absorbing layer 303, which may be made of any material as long as the light absorbing layer 303 has good light absorbing ability.

In the above four implementing modes, the first opening 3011 is a rectangular opening and the light-emitting area 201 is a rectangular area as an example. A size of the first opening 3011 may include a length and a width of the first opening 3011, and a size of the light-emitting area 201 may include a length and a width of the light-emitting area 201. In FIG. 2 to FIG. 8, as an example, the length of the first opening 3011 is greater than that of the light-emitting area 201, and the width of the first opening 3011 is greater than that of the light-emitting area 201. In other embodiments, at least one of the length and the width of the first opening 3011 may be larger than that of the light-emitting area 201, or the first opening may be a circular opening or an opening of any other shape while the light-emitting area may be a circular area or an area of any other shape, and embodiments of the present disclosure does not limit shapes of the first opening 3011 and of the light-emitting area 201.

The above four implementing mode may be applied alone or in any combination. Whether applied alone or in any combination, it can alleviate the poor color-mixing of the display panel. Compared with one of the above-mentioned four implementing modes applied alone, a combination of at least two of the above-mentioned four implementing modes may better alleviate the poor color-mixing of the display panel. In addition, compared with the fourth implementing mode, the light emitted by the light-emitting area is not absorbed in the first to third implementing mods, thus the light-exit rate of light emitted by the light-emitting area (refers to a ratio of the intensity of light emitted from the display panel to that of light emitted from the light-emitting area, among light emitted from the light-emitting area) is higher.

In an optional embodiment of the present disclosure, the first reflecting layer 301 is of a single-layer structure, and a material of the first reflecting layer 301 includes at least one of Mo, Al, Ti, and Ag. For example, the material of the first reflecting layer 301 is one of Mo, Al, Ti, and Ag; or the material of the first reflecting layer 301 is an alloy material of at least two of Mo, Al, Ti, and Ag. In another optional embodiment of the present disclosure, the first reflecting layer 301 is of a multi-layer structure. For example, the first reflecting layer 301 includes a first film layer, a second film layer, and a third film layer which are laminated, and the first film layer, the second film layer and the third film layer satisfy one of the following: (1) materials of the first film layer and the third film layer are both Ti, and a material of the second film layer is Al; (2) materials of the first film layer and the third film layer are both ITO, and a material of the second film layer is Ag.

In an optional embodiment of the present disclosure, the second reflecting layer 302 is of a single-layer structure, and a material of the second reflecting layer 302 includes at least one of Mo, Al, Ti, and Ag. For example, the material of the second reflecting layer 302 is one of Mo, Al, Ti, and Ag; or the material of the second reflecting layer 302 is an alloy material of at least two of Mo, Al, Ti, and Ag. In another optional embodiment of the present disclosure, the second reflecting layer 302 is of a multi-layer structure. For example, the second reflecting layer 302 includes a first film layer, a second film layer, and a third film layer which are laminated, and the first film layer, the second film layer and the third film layer satisfy one of the following: (1) materials of the first film layer and the third film layer are both Ti, and a material of the second film layer is Al; (2) materials of the first film layer and the third film layer are both ITO, and a material of the second film layer is Ag.

In an optional embodiment of the present disclosure, the first reflecting layer 301 and the second reflecting layer 302 may have the same film layer structure, and the first reflecting layer 301 and the second reflecting layer 302 may be made of the same material. In this way, the first reflecting layer 301 and the second reflecting layer 302 may be prepared at the same time, thereby simplifying a manufacturing process of the display panel.

Optionally, referring to FIG. 3, FIG. 5, FIG. 7 and FIG. 8 again, the display panel further includes light-emitting units 40. The light-emitting units 40 (a light-emitting unit 40G and a light-emitting unit 40B in FIG. 3, FIG. 5, FIG. 7 and FIG. 8 are collectively referred to as the light-emitting units 40) are disposed in the light-emitting areas 201. For example, the light-emitting unit 40G is disposed in the light-emitting area 201G, and the light-emitting unit 40B is disposed in the light-emitting area 201B. The light-emitting unit 40 may be an organic light-emitting diode (OLED). The light-emitting unit 40 includes an anode 401, an organic light-emitting layer 402 and a cathode 403, wherein the anode 401, the organic light-emitting layer 402 and the cathode 403 are laminated in sequence. The anode 401 is disposed in the light-emitting area 201 and may be a bulk electrode. Both the organic light-emitting layer 402 and the cathode 403 are of a whole-layer structure. Multiple light-emitting units 40 in the display panel share the same organic light-emitting layer 402 and share the same cathode 403. In the embodiment of the present disclosure, the light-emitting units 40 are individually controlled by individually controlling the anodes 401 in the display panel.

The anode 401 may be of a single-layer structure or a multi-layer structure. For example, the anode 401 is of a single-layer structure made of ITO; alternatively, the anode 401 includes a first film layer, a second film layer, and a third film layer which are laminated, wherein materials of the first film layer and the third film layer are ITO, and a material of the second film layer is Ag. The cathode 403 may be of a single-layer structure or a multi-layer structure. For example, the cathode 403 is of a single-layer structure made of Ag or magnesium (Mg); alternatively, the cathode 403 includes a first film layer and a second film layer which are laminated, wherein a material of the first film layer is Ag, and a material of the second film layer is Mg, which is not limited in the embodiment of the present disclosure.

Optionally, referring to FIG. 3, FIG. 5, FIG. 7 and FIG. 8 again, the display panel further includes an encapsulating structure 50. The encapsulating structure 50 is disposed between the light-emitting unit 40 and the first reflecting layer 301. The encapsulating structure 50 is configured for encapsulating the light-emitting units 40 in the display panel to prevent external moisture, oxygen, etc. from corroding the light-emitting units 40. The encapsulating structure 50 may be a Thin Film Encapsulation (TFE) structure. The TFE structure includes inorganic and organic layers which are alternately laminated. For example, as shown in FIG. 3, FIG. 5, FIG. 7 and FIG. 8, the encapsulating structure 50 includes a first inorganic layer 501, an organic layer 502, and a second inorganic layer 503 which are laminated in sequence. A material of the inorganic layer may be one or a combination of two or more of silicon oxide (SiOx), silicon nitride (SiNx) and silicon oxynitride (SiOxNy), and a material of the organic layer may be an organic resin or the like.

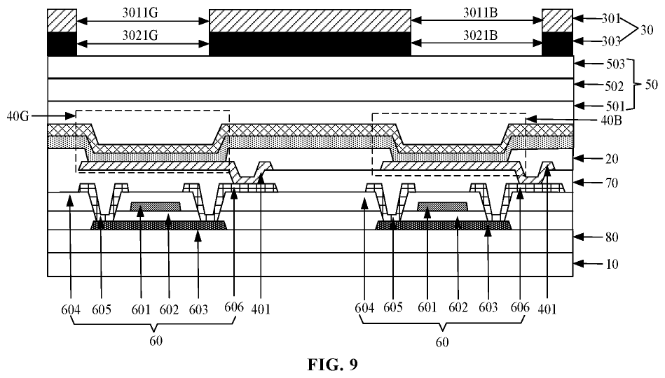

Optionally, FIG. 9 is referred to, which shows a sectional view of still another display panel according to an embodiment of the present disclosure. Based on FIG. 8, the display panel further includes switch units 60. The switch units 60 are disposed between the base substrate 10 and the pixel defining layer 20, and are connected to the light-emitting units 40. The switch units 60 are configured to control the light-emitting units 40 connected thereto to be turned on or off. The switch unit 60 may be a TFT.

As shown in FIG. 9, the switch unit 60 includes a gate 601, a gate insulating layer 602, an active layer 603, an interlayer insulating layer 604, a source 605, and a drain 606. The source 605 and the drain 606 are disposed on the same layer. The interlayer insulating layer 604 and the gate insulating layer 602 are laminated and disposed between the source 605 and the active layer 603. The interlayer insulating layer 604 and the gate insulating layer 602 respectively have a plurality of via holes, and the via holes in the interlayer insulating layer 604 are connected to the via holes in the gate insulating layer 602. The source 605 is connected to the active layer 603 through the via holes in the interlayer insulating layer 604 and the via holes in the gate insulating layer 602 sequentially. The drain 606 is connected to the active layer 603 through the via holes in the interlayer insulating layer 604 and the via holes in the gate insulating layer 602 sequentially. The source 605 and the drain 606 are connected to the active layer 603 through different via holes. The drain 606 of the switch unit 60 is connected to the anode 402 of the light-emitting unit 40. For example, the display panel further includes a flat layer 70 disposed between the switch unit 60 and the light-emitting unit 40. The flat layer 70 has a via hole, and the anode 401 of the light-emitting unit 40 is connected to the drain 606 of the switch unit 60 through the via hole in the flat layer 70.

A material of the active layer 603 may include Low-Temperature Polycrystalline Silicon (LTPS) or a metal oxide. For example, the metal oxide may be an indium gallium zinc oxide (IGZO). The display panel includes a plurality of switch units 60, and the plurality of switch units 60 include at least one of a low-temperature polycrystalline silicon TFT (i.e., a material of the active layer of the TFT is a low-temperature polycrystalline silicon) and a metal oxide TFT (i.e., a material of the active layer of the TFT is a metal oxide).

Optionally, the plurality of switch units 60 in the display panel may include at least one of a top-gate TFT and a bottom-gate TFT. FIG. 9 illustrates that the switch unit 60 is a top-gate TFT as an example, which does not limit the present disclosure, and the switch unit 60 may also be a bottom-gate TFT.

In the embodiment of the present disclosure, the display panel includes red sub-pixels, green sub-pixels, and blue sub-pixels, and each light-emitting unit 40 belongs to one sub-pixel. The display panel also includes a backplane circuit for each sub-pixel. For example, the backplane circuit may be a 7T1C circuit (i.e., the backplane circuit includes 7 TFTs and one capacitor). The switch unit 60 is disposed in the backplane circuit and may be a TFT in the backplane circuit. TFTs in the same backplane circuit include at least one of a low-temperature polycrystalline silicon TFT and a metal oxide TFT, and TFTs in the same backplane circuit include at least one of a top-gate TFT and a bottom-gate TFT.

Optionally, referring to FIG. 9 again, the display panel further includes a buffer layer 80 disposed between the base substrate 10 and the switch unit 60. The buffer layer 80 may be of a single-layer structure or a multi-layer structure, and a material of the buffer layer 80 may be one or a combination of two or more of SiOx, SiNx, and SiOxNy.

The display panel according to the embodiment of the present disclosure may be an organic light-emitting display panel, for example, an OLED display panel. The OLED display panel may be an active-matrix organic light-emitting diode (AMOLED). The base substrate 10 may be a rigid substrate made of a light-guiding non-metallic transparent material with certain sturdiness, such as glass or quartz. Alternatively, the base substrate 10 may be a flexible substrate made of flexible materials such as polyimide (PI). In a case where the base substrate 10 is a flexible substrate, the display panel may be a flexible display panel. The display panel may be applied to the field of AMOLED mirror display.

The embodiment of the present disclosure takes the display panel shown in FIG. 8 as an example for description. The display panels in FIG. 3, FIG. 5 and FIG. 7 also include a switch unit, a buffer layer and other structures. In FIG. 2, FIG. 4 and FIG. 6, the light-emitting area 201R is configured for arranging red sub-pixels, the light-emitting area 201G is configured for arranging green sub-pixels, and the light-emitting area 201B is configured for arranging blue sub-pixels. Arrangement positions of the sub-pixels of respective colors and a color scheme of the sub-pixels in FIG. 2, FIG. 4 and FIG. 6 are only exemplary and do not limit the present disclosure. Arrangement positions of the sub-pixels of respective colors and the color scheme of the sub-pixels may also be implemented in other ways, which are not described in details.

FIG. 1 to FIG. 9 only show structures related to technical solutions of the present disclosure in the display panel, and are only used as examples of the present disclosure. The display panel may further include other structures, for example, the display panel may further include a gate metal structure, data lines and other structures, wherein the gate metal structure and the gate are disposed on the same layer, and the gate metal structure may be configured as a plate of a capacitor or as a gate wire.

Embodiments of the present disclosure provide a mirror display apparatus. The mirror display apparatus includes the display panel according to the foregoing embodiments, and the display panel may be an organic light-emitting display panel.

The mirror display apparatus has characteristics and advantages of the display panel of the foregoing embodiments. A mirror display effect of the mirror display apparatus is better, and a possibility of defects such as cross-color and color-mixing is low.

Embodiments of the present disclosure provide a method for manufacturing a display panel. The method for manufacturing a display panel may be implemented to manufacture the display panel according to the foregoing embodiments, and may include the following steps:

In S101, a base substrate is provided.

The base substrate is a rigid substrate made of a light-guiding non-metallic transparent material with certain sturdiness, such as glass or quartz. Alternatively, the base substrate is a flexible substrate made of a flexible material such as PI.

In S102, a pixel defining layer is formed on the base substrate, and the pixel defining layer defines a plurality of light-emitting areas.

Materials of the pixel defining layer may include transparent organic materials such as organic resins. Alternatively, materials of the pixel defining layer may include transparent inorganic materials such as SiOx, SiNx, or SiOxNy. The material of the pixel defining layer may be SiOx as an example. A SiOx material layer may be formed on the base substrate by any process of deposition, magnetron sputtering or thermal evaporation and so on. The pixel defining layer may be acquired by processing the SiOx material layer through a one-time patterning process, and may define a plurality of light-emitting areas.

In S103, a light adjusting layer is formed. The light adjusting layer includes a first reflecting layer. The first reflecting layer is disposed at a side of the pixel defining layer away from the base substrate, and has first openings in areas corresponding to the light-emitting areas.

The first reflecting layer may be of a single-layer structure, and a material of the first reflecting layer includes at least one of Mo, Al, Ti, and Ag. Alternatively, the first reflecting layer may be of a multi-layer structure. As an example, the first reflecting layer is of a single-layer structure, and the material of the first reflecting layer is Al, then forming the light adjusting layer may include: forming an Al material layer at a side of the pixel defining layer away from the base substrate by any process of deposition, magnetron sputtering or thermal evaporation and so on, and acquiring the first reflecting layer by processing the Al material layer by a one-time patterning process. An area of the first reflecting layer corresponding to the light-emitting areas includes first openings, and there may also be light-leaking gaps in the first reflecting layer.

Optionally, the light adjusting layer further includes a second reflecting layer. The first reflecting layer and the second reflecting layer are disposed on the same layer, and may be prepared by the same process, so that the second reflecting layer may be formed in a process of forming the first reflecting layer. On the base substrate, an orthogonal projection of the second reflecting layer is within an orthogonal projection of the light-emitting area, and an area of the orthogonal projection of the second reflecting layer is smaller than that of the orthogonal projection of the light-emitting area.

Optionally, the light adjusting layer further includes a light absorbing layer disposed between the pixel defining layer and the first reflecting layer, then forming the light adjusting layer may further include: before forming the first reflecting layer, forming a light absorbing material layer at a side of the pixel defining layer away from the base substrate through any process of deposition, magnetron sputtering or thermal evaporation and so on, and acquiring the light absorbing layer by processing the light absorbing material layer by a one-time patterning process.

Optionally, the display panel further includes a buffer layer, a switch unit, a flat layer, a light-emitting unit, and an encapsulating structure disposed in a direction away from the base substrate, then the method also includes the following steps:

In S104, a buffer layer is formed on the base substrate.

A material of the buffer layer may be one or a combination of two or more of SiOx, SiNx, or SiOxNy. As an example, the material of the buffer layer is SiOx, and the buffer layer is formed on the base substrate by any process of deposition, coating, or sputtering and so on.

In S105, a switch unit is formed at a side of the buffer layer away from the base substrate.

Optionally, an active layer, a gate insulating layer, a gate, an interlayer insulating layer, and a source-drain pattern are sequentially formed at the side of the buffer layer away from the base substrate to acquire the switch unit. The source-drain pattern includes a source and a drain. The interlayer insulating layer and the gate insulating layer respectively have a plurality of via holes, and the via holes in the interlayer insulating layer are connected with the via holes in the gate insulating layer. The source is connected to the active layer through the via holes in the interlayer insulating layer and the via holes in the gate insulating layer sequentially. The drain is connected to the active layer through the via holes in the interlayer insulating layer and the via holes in the gate insulating layer sequentially. The source and the drain are connected to the active layer through different via holes.

In S106, a flat layer is formed at a side of the switch unit away from the base substrate.

A material of the flat layer may include a transparent organic material such as an organic resin, or the material of the flat layer may include a transparent inorganic material such as SiOx, SiNx, or SiOxNy. As an example, the material of the flat layer is an organic resin, then a resin material layer may be formed on the base substrate by any process of deposition, coating or sputtering and so on, and the flat layer may be acquired by exposing and developing sequentially the resin material layer, wherein the flat layer has via holes.

In S107, a light-emitting unit is formed at a side of the flat layer away from the base substrate.

Optionally, an anode, a light-emitting layer, and a cathode are sequentially formed on the side of the flat layer away from the base substrate to acquire a light-emitting unit. For example, an anode is formed first at the side of the flat layer away from the base substrate, and the anode is connected to the drain of the switch unit through a via hole in the flat layer. After the anode is formed, the above-mentioned S102 may be performed to form a pixel defining layer. After S102 is performed, a light-emitting layer and a cathode are sequentially formed at a side of the pixel defining layer away from the base substrate.

In S108, an encapsulating structure is formed at a side of the light-emitting unit away from the base substrate.

Optionally, a first inorganic layer, an organic layer, and a second inorganic layer are sequentially formed at the side of the light-emitting unit away from the base substrate, and the first inorganic layer, the organic layer, and the second inorganic layer are sequentially laminated to form the encapsulating structure.

After S108 is performed, the above-mentioned S103 may be performed to form a light adjusting layer.

The one-time patterning process described in the embodiments of the present disclosure may include: photoresist coating, exposure, development, etching and photoresist stripping. Therefore, processing a material layer (for example, an aluminum material layer) through the one-time patterning process may include: firstly, forming a photoresist layer by coating a layer of a photoresist on the material layer (for example, the aluminum material layer); then, exposing the photoresist by using a mask so that the photoresist forms a fully exposed area and a non-exposed area; next, processing the exposed photoresist through a development process, so that the photoresist in the fully exposed area is completely removed, and all the photoresist in the non-exposed area is retained; afterwards, etching the area corresponding to the fully exposed area on the material layer (for example, the aluminum material layer) through an etching process; and finally, striping the photoresist in the non-exposed area, the area corresponding to the non-exposed area on the material layer (for example, the aluminum material layer) forming a corresponding structure (for example, the first reflecting layer). The embodiment of the present disclosure uses a positive photoresist as an example to describe the one-time patterning process. The photoresist used in the one-time patterning process may be a negative photoresist, which is similar to the process of using a positive photoresist, and will not be repeated by the embodiment of the present disclosure in detail.

The above describes the embodiments of the present disclosure, but the present disclosure is not limited to the details of the above embodiments. Various simple modifications can be made to the technical solutions of the present disclosure within the technical concept of the present disclosure, and should fall into the protection scope of the present disclosure. In a case where the respective technical features described in the above embodiments do not conflict with one another, the respective technical features can be combined in any suitable form.

In the foregoing embodiments, an orthogonal projection of a member or structure on a plane means an orthogonal projection of the member or structure on this plane. For example, an orthogonal projection of a first opening on a base substrate means an orthogonal projection of the first opening on the base substrate.

Unless otherwise defined, the technical terms or scientific terms used in the embodiments of the present disclosure shall be taken to mean the ordinary meanings as understood by the ordinary skill in the art to which the present disclosure belongs. The terms “first”, “second” and the like do not denote any order, quantity or importance, but are merely used to distinguish different components. The terms “comprise”, “include” and the like are intended to mean that the elements or objects before said term cover the elements or objects or equivalents listed after said term, without excluding other elements or objects. The terms “include”, “comprise” and similar terms mean that elements or objects appearing before the term cover the listed elements or objects and its equivalents appearing after the term while other elements or objects are not excluded. The terms “connected”, “coupled” and similar terms are not limited to physical or mechanical connections, and may include electrical connection and the connection may be direct or indirect. Orientation or positional relations denoted by the terms “upper”, “lower”, “top”, “bottom” and the like are only used to indicate the relative orientation or positional relations shown in the figures, are used for the sake of simplified description of the present disclosure, are not intended to indicate or imply that the apparatuses or elements must have special orientations or must be configured and operated in specific orientations, and therefore should not be understood as limitations of the present disclosure. The term “at least one” refers to one or a plurality, and the term “plurality” refers to two or more. The term “and/or” describes an association relation between associated objects and indicates three types of possible relations. For example, A and/or B may be expressed as the following three cases: A exists alone, A and B exist concurrently, and B exists alone. The character “/” generally indicates an “or” relation unless otherwise specified. For example, “A/B” refers to A or B. The terms such as “an embodiment”, “some embodiments”, “an example” and “some examples” mean that the features, structures, materials or characteristics described in combination with the embodiment or example are included in at least one embodiment or example of the present disclosure. Furthermore, the described features, structures, materials or characteristics may be combined in any suitable manner in any one or more embodiments or examples. When there is no conflict, those skilled in the art can combine different embodiments or examples described in the present disclosure or the features of different embodiments or examples described in the present disclosure.

It should be noted that in the drawings, the dimensions of the layers and areas may be exaggerated for the clarity of the drawings. It can be understood that when an element or layer is named to be disposed “on” another element or layer, the element or layer may be directly disposed on the another element, or there may be an intermediate layer. Further, it can be understood that when an element or layer is named to be disposed “under” another element or layer, the element or layer may be directly disposed under the another element, or there may be at least one intermediate layer or element. Further, it can be understood that when an element or layer is named to be disposed “between” two layers or two elements, the element or layer may be the exclusive one between the two layers or two elements, or there may be at least one intermediate layer or element. Similar reference signs refer to similar elements throughout the whole text.

Although the embodiments of the present disclosure are illustrated and described as above, these embodiments are exemplary and cannot be understood as limitations of the present disclosure. Any person skilled in the art can make possible changes, modifications substitutions and variations without departing from the spirit of the present disclosure.

What is claimed is:

1. A display panel, comprising:
a base substrate;
a pixel defining layer which is disposed on the base substrate and defines a plurality of light-emitting areas; and
a light adjusting layer comprising a first reflecting layer, wherein the first reflecting layer is disposed at a side of the pixel defining layer away from the base substrate, and has first openings in areas corresponding to the light-emitting areas;
wherein the light adjusting layer is configured to block at least a part of light directed at adjacent light-emitting areas for each of the light-emitting areas.

2. The display panel according to claim 1, wherein for each of the first opening, a size of the first opening is larger than a size of a corresponding light-emitting area, and an orthogonal projection of the first opening on the base substrate covers an orthogonal projection of the corresponding light-emitting area on the base substrate.

3. The display panel according to claim 1, wherein the light adjusting layer further comprises a second reflecting layer disposed at the side of the pixel defining layer away from the base substrate; and an orthogonal projection of the second reflecting layer on the base substrate is within an orthogonal projection of the light-emitting areas on the base substrate, and an area of the orthogonal projection of the second reflecting layer on the base substrate is smaller than an area of the orthogonal projection of the light-emitting areas on the base substrate.

4. The display panel according to claim 3, wherein for each of the first openings, an orthogonal projection of the first opening on the base substrate covers an orthogonal projection of a corresponding light-emitting area on the base substrate.

5. The display panel according to claim 3, wherein the second reflecting layer and the first reflecting layer are disposed in the same layer.

6. The display panel according to claim 1, wherein the first reflecting layer further comprises light-leaking gaps; and an orthogonal projection of the light-leaking gaps on the base substrate is staggered from an orthogonal projection of the light-emitting areas on the base substrate.

7. The display panel according to claim 6, wherein the light-leaking gaps are disposed to surround each of the light-emitting areas.

8. The display panel according to claim 6, wherein for each of the first openings, an orthogonal projection of the first opening on the base substrate covers an orthogonal projection of a corresponding light-emitting area on the base substrate.

9. The display panel according to claim 1, wherein the light adjusting layer further comprises a light absorbing layer disposed between the pixel defining layer and the first reflecting layer, the light absorbing layer comprises second openings, and an orthogonal projection of the second openings on the base substrate overlaps with an orthogonal projection of the first openings on the base substrate.

10. The display panel according to claim 9, wherein for each of the first openings, an orthogonal projection of the first opening on the base substrate covers an orthogonal projection of a corresponding light-emitting area on the base substrate.

11. The display panel according to claim 9, wherein a material of the light absorbing layer comprises at least one of black MoO₃ and a black resin.

12. The display panel according to claim 1, wherein the first reflecting layer is a one-layer film, and a material of the first reflecting layer comprises at least one of Mo, Al, Ti and Ag.

13. The display panel according to claim 1, wherein
the first reflecting layer comprises a first film layer, a second film layer and a third film layer which are laminated, and the first film layer, the second film layer and the third film layer satisfy one of the followings:
materials of the first film layer and the third film layer are both Ti, and a material of the second film layer is Al;
materials of the first film layer and the third film layer are both ITO, and a material of the second film layer is Ag.

14. The display panel according to claim 3, wherein the second reflecting layer is a one-layer film, and a material of the second reflecting layer comprises at least one of Mo, Al, Ti and Ag.

15. The display panel according to claim 3, wherein
the second reflecting layer comprises a first film layer, a second film layer and a third film layer which are laminated, and the first film layer, the second film layer and the third film layer satisfy one of the followings:
materials of the first film layer and the third film layer are both Ti, and a material of the second film layer is Al;
materials of the first film layer and the third film layer are both ITO, and a material of the second film layer is Ag.

16. The display panel according to claim 1, further comprising:
a switch unit disposed between the base substrate and the pixel defining layer;
a light-emitting unit disposed in the light-emitting area and connected to the switch unit; and
an encapsulating structure disposed between the light-emitting unit and the first reflecting layer.

17. The display panel according to claim 16, wherein the switch unit of the display panel comprises at least one of a low-temperature polycrystalline silicon thin film transistor and a metal oxide thin film transistor.

18. The display panel according to claim 16, wherein the encapsulating structure is a thin film encapsulation structure.

19. The display panel according to claim 1, wherein
for each of the first openings, a size of the first openings is larger than a size of a corresponding light-emitting area, and an orthogonal projection of the first opening on the base substrate covers an orthogonal projection of the corresponding light-emitting area on the base substrate; the first reflecting layer further comprises light-leaking gaps disposed to surround each of the light-emitting areas;
the light adjusting layer further comprises a second reflecting layer and a light-absorbing layer; the second reflecting layer is disposed at the side of the pixel defining layer away from the base substrate; an orthogonal projection of the second reflecting layer on the base substrate is within an orthogonal projection of the light-emitting areas on the base substrate, and an area of the orthogonal projection of the second reflecting layer on the base substrate is smaller than an area of the orthogonal projection of the light-emitting areas on the base substrate; the light absorbing layer is disposed between the pixel defining layer and the first reflecting layer and comprises second openings; and an orthogonal projection of the second openings on the base substrate overlaps with an orthogonal projection of the first openings on the base substrate; and
the display panel further comprises: a switch unit disposed between the base substrate and the pixel defining layer; a light-emitting unit disposed in the light-emitting area and connected to the switch unit; and an encapsulating structure disposed between the light-emitting unit and the first reflecting layer.

20. A mirror display apparatus comprising a display panel, the display panel comprising:
a base substrate;
a pixel defining layer disposed on the base substrate and defining a plurality of light-emitting areas; and
a light adjusting layer comprising a first reflecting layer, wherein the first reflecting layer is disposed at a side of the pixel defining layer away from the base substrate, and has first openings in areas corresponding to the light-emitting areas,
wherein the light adjusting layer is configured to block at least a part of light directed at adjacent light-emitting areas for each of the light-emitting areas.
